(19) United States
(12) Patent Application Publication
(10) Pub. No.: US 2026/0181885 A1
(43) Pub. Date: Jun. 25, 2026

(54) ELECTRONIC METHOD AND DEVICE COMPRISING MEMORY CELL

(71) Applicant: STMicroelectronics International N.V., Geneva (CH)

(72) Inventors: Madjid Akbal, Trets (FR); Franck Melul, Aubagne (FR); Khaled Alkema, Marseille (FR)

(21) Appl. No.: 19/429,886

(22) Filed: Dec. 22, 2025

(30) Foreign Application Priority Data
Dec. 24, 2024 (FR) FR2415210

(51) Int. Cl. H10B 41/30; G11C 16/04

(52) U.S. Cl. CPC H10B 41/30; G11C 16/0425

(57) ABSTRACT

The present description concerns an electronic method and device comprising a memory cell comprising a first semiconductor well of a first conductivity type, a second semiconductor well of the first conductivity type, a first layer on a lower surface of the first and second wells, an insulated conductive wall separating the first and second wells, a third semiconductor well of the second conductivity type located in the first well, a fourth semiconductor well of the second conductivity type located in the second well, and a stack of layers extending over the first and second wells and the wall, the stack comprising a second insulating layer, a third floating gate layer, a fourth insulating layer, and a fifth control gate layer.

### CROSS-REFERENCE TO RELATED APPLICATIONS

This application claims the benefit of French patent application number FR 2415210, filed on Dec. 24, 2024, which application is hereby incorporated herein by reference.

### TECHNICAL FIELD

The present disclosure generally concerns electronic devices and more precisely devices comprising a memory cell and their methods of use.

### BACKGROUND

There exist many different types of memory cells. There exist so-called eSTM (embedded Select in Trench Memory) memory cells. An eSTM memory cell is a rewritable memory cell typically used in flash-type memory circuits. There further exists so-called EEPROM (Electrically-Erasable Programmable Read-Only Memory) memory cells. An EEPROM memory cell is a non-volatile type of memory.

### SUMMARY

An embodiment provides an electronic device comprising a memory cell, the memory cell comprising: a first doped semiconductor well of a first conductivity type; a second doped semiconductor well of the same conductivity type as the first well; a first layer in contact with a lower surface of the first and second wells; an insulated conductive wall separating the first and second wells; a third semiconductor well located in the first well, the third well being doped with a second conductivity type opposite to the first conductivity type; a fourth semiconductor well located in the second well, the fourth well being doped with the second conductivity type; and a stack of layers extending over the first and second wells and the wall, the stack comprising a second insulating layer, a third layer forming a floating gate, a fourth insulating layer, and a fifth layer forming a control gate.

An embodiment provides a method of using an electronic device comprising a memory cell, the memory cell comprising: a first doped semiconductor well of a first conductivity type; a second doped semiconductor well of the same conductivity type as the first well; a first layer in contact with a lower surface of the first and second wells; an insulated conductive wall separating the first and second wells; a third semiconductor well located in the first well, the third well being doped with a second conductivity type opposite to the first conductivity type; a fourth semiconductor well located in the second well, the fourth well being doped with the second conductivity type; and a stack of layers extending over the first and second wells and the wall, the stack comprising a second insulating layer, a third layer forming a floating gate, a fourth insulating layer, and a fifth layer forming a control gate, the method comprising a step of reading of a data item contained in the cell, a step of writing of the data item into the cell, and a step of erasing of the cell.

According to an embodiment, the fourth well separates the second well from the second layer.

According to an embodiment, during the write or erase step, the cell is biased in such a way that charges, electrons or holes, are injected into the third layer from the fourth well through the second layer by tunnel effect.

According to an embodiment, the fourth well is separated from the wall by a portion of the second well.

According to an embodiment, during the write or erase step, the cell is biased in such a way that charges, electrons or holes, are injected into the third layer from the second well through the second layer by tunnel effect.

According to an embodiment, the conductive insulating wall comprises a conductive core and an insulating cover.

According to an embodiment, a portion of the cover is covered by an insulating region made of a material different from the material of the cover, the region separating the fourth well from the wall, the second well being in contact with the wall.

According to an embodiment, the core extends from the lower surface of the second layer to a level in the first layer.

According to an embodiment, the core is separated from the second layer by a portion of the cover.

According to an embodiment, the second layer comprises a first portion having a first thickness and a second portion having a second thickness, smaller than the first thickness, the first portion being located opposite the first well and the second portion being located opposite the second well.

According to an embodiment, the thickness of the first portion is at least one and a half times greater than the thickness of the second portion.

According to an embodiment, during the readout step, the cell is biased so as to form a current between the first layer and the third well.

According to an embodiment, during the write or erase step, the cell is biased in such a way that a current is formed between the first layer and the third well, charges, electrons or holes, being injected into the third layer by injection of hot carriers through the second layer.

According to an embodiment, during the write or erase step, the cell is biased in such a way that a current is formed between the first layer and the fourth well, charges, electrons or holes, being injected into the third layer by injection of hot carriers through the second layer.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows views A, B, C, and D of an embodiment of a memory cell;

FIG. 2A and FIG. 2B show operating modes of the cell of FIG. 1;

FIG. 3 shows another embodiment of a memory cell;

FIG. 4 shows another embodiment of a memory cell;

FIG. 5 shows another embodiment of a memory cell;

FIG. 6A, FIG. 6B, and FIG. 6C show operating modes of the cell of FIG. 5;

FIG. 7 shows another embodiment of a memory cell; and

FIG. 8 shows an operating mode of the cell of FIG. 7.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only those steps and elements that are useful for understanding the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

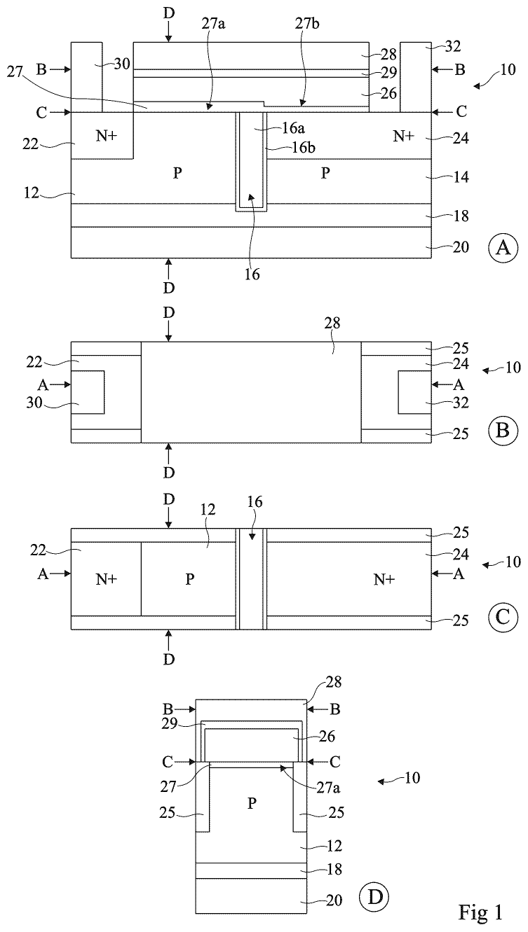

FIG. 1 shows views A, B, C, and D of an embodiment of a memory cell 10. More specifically, FIG. 1 comprises: a cross-section view A along a plane A-A of views B and C; a top view B along a plane B-B of views A and D; a top view C along a plane C-C of views A and D; and a cross-section view D along a plane D-D of views B and C.

Planes B-B and C-C are parallel to each other and orthogonal to planes A-A and D-D. Plane A-A is orthogonal to planes B-B, C-C and D-D. Similarly, plane D-D is orthogonal to planes A-A, B-B and C-C. Plane A-A corresponds to the direction of a bit line in an array of identical or similar elementary cells. Plane D-D corresponds to the direction of a word line of the array.

Memory cell 10 comprises a well 12. Well 12 is made of a semiconductor material, for example of silicon. Well 12 is doped with a first conductivity type, for example type P. Well 12 is for example doped with boron. The dopant concentration in well 12 is, for example, in the range from 10¹⁴ to 5·10¹⁵ atoms·cm⁻³.

Cell 10 further comprises a well 14. Well 14 is made of a semiconductor material, for example of silicon. Well 14 is doped with the first conductivity type, that is, the same conductivity type as well 12, for example type P. Well 14 is for example doped with boron. The dopant concentration in well 14 is, for example, in the range from 10¹⁴ to 5.10¹⁵ atoms·cm⁻³.

Cell 10 further comprises a wall 16 separating wells 12 and 14. Wall 16 for example comprises a core 16a, for example made of a metal or of a semiconductor material, preferably of polysilicon, and an insulating cover 16b surrounding core 16a, for example made of silicon oxide. In particular, insulating cover 16b separates core 16a from wells 12 and 14. Preferably, wells 12 and 14 are entirely separated by wall 16. Wall 16 preferably extends at least along the entire height of wells 12 and 14. Thus, wells 12 and 14 are preferably not in contact with each other. Wells 12 and 14 are preferably in contact with wall 16.

Preferably, wells 12 and 14 have lower surfaces coplanar with each other. Preferably, cell 10 comprises a layer 18 having the lower surfaces of wells 12 and 14 resting thereon. In this example, the lower surfaces of wells 12 and 14 are in contact with the upper surface of layer 18. Layer 18 is preferably made of a semiconductor material, for example, silicon, for example, doped silicon of a second conductivity type opposite to the first conductivity type, for example type N. Layer 18 rests, for example, on a doped substrate 20 of the first conductivity type, for example type P. Substrate 20 is for example made of a boron-doped semiconductor material.

Preferably, the lower surface of wall 16 is located in layer 18. Wall 16 crosses, preferably partially, layer 18. Preferably, a portion of wall 16, including at least a portion of core 16a, is laterally surrounded by layer 18. Preferably, wall 16 does not cross, even partially, substrate 20.

Cell 10 comprises a well 22 located in an upper portion of the well 12. Well 22 is made of a semiconductor material, for example of silicon. Well 22 is doped with the second conductivity type, for example type N (N+). Well 22 is doped with the conductivity type opposite to that of well 12. Well 22 is for example doped with phosphorus. The dopant concentration in well 22 is, for example, in the range from 1018 to 1020 atoms·cm⁻³.

Well 22 is separated from wall 16 by a portion of well 12. In other words, a portion of well 12 is located between well 22 and wall 16. Wall 16 and well 22 are thus not in contact with each other. Well 22 extends from the upper surface of well 12. The upper surface of well 22 is preferably coplanar with the upper surface of wall 16 and with the upper surface of the portion of well 12 located between well 22 and wall 16.

Similarly, cell 10 comprises a well 24 located in an upper portion of well 14. Well 24 is made of a semiconductor material, for example, of silicon. Well 24 is doped with the second conductivity type, for example type N (N+). Well 24 is doped with the conductivity type opposite to the conductivity type of well 14. Well 24 is for example doped with phosphorus. The dopant concentration in well 24 is, for example, in the range from 1018 to 1020 atoms·cm⁻³.

Well 24 preferably extends above well 14. Well 24 thus extends over, and preferably in contact with, the upper surface of well 14. Well 24 is in contact with wall 16. Well 24 extends from the upper surface of well 12 and of wall 18. The upper surface of well 24 is preferably coplanar with the upper surface of wall 16. Preferably, well 14 does not extend up to the level of the upper surface of wall 16. Thus, an upper portion of wall 16 is in contact with well 12 and well 24, and a lower portion of wall 16 is in contact with well 12 and well 14.

The plane C-C of view C illustrates the upper surfaces of wells 12, 22, 24 and of wall 16. In plane C-C, the cell thus comprises, from left to right, well 22, well 12, wall 16, and well 24.

The doping or conductivity type of well 12 is the same type as the doping type of well 14. Similarly, the doping type of well 22 is the same as the doping type of well 24. Further, the doping type of well 22 is the type opposite to the doping type of well 12. The doping type of well 24 is the type opposite to the doping type of well 14. Thus, wells 22 and 14 have opposite doping types and wells 24 and 12 have opposite doping types.

Cell 10 is separated from neighboring cells belonging to different rows by insulating walls 25. Insulating walls 25 are for example made of silicon oxide. Insulating walls 25 preferably extend from the plane of the upper surfaces of wells 22 and 24, that is, plane C-C. Walls 25 preferably extend along the entire cell in the row direction. Thus, walls 25 extend along wells 22, 24, 12, and 14. Walls 25 are preferably crossed by wall 16. Walls 25 preferably extend along a height smaller than the height of wall 16, that is, a height smaller than the distance between plane C-C and layer 18. Thus, walls 25 preferably do not extend along the entire height of wells 12 and 14. This enables to electrically connect the wells 12 and 14 of a cell 10 to neighboring cells 10. Walls 25 are preferably separated from layer 18 by a portion of well 12 or of well 14. Preferably, walls 25 extend along a height greater than the height of wells 22 and 24.

Cell 10 further comprises a stack of an insulating layer 27, of a layer 26 of a metal or of a semiconductor material, for example polysilicon, of an insulating layer 29, and of a layer 28 of a metal or of a semiconductor material, for example polysilicon. For example, layer 27 is made of silicon oxide and layer 29 is a stack of a silicon oxide layer, of a silicon nitride layer, and of a silicon oxide layer. Preferably, layers 26 and 28 are made of the same material, for example of polysilicon.

Layer 27 rests on the upper surface of wells 12, 22, and 24. Layer 26 rests on layer 27. Preferably, layer 26 has horizontal dimensions smaller than the horizontal dimensions of layer 27, that is, smaller dimensions in the bit and word line directions. Preferably, layer 27 continuously extends over the entire upper surface of well 12 and at least partially over the upper surface of wells 22 and 24. Layer 27 preferably does not extend in contact with well 14. Well 14 is preferably entirely separated from layer 27 by well 24. Layer 27 extends, in the column direction, across the entire width of wells 22 and 24. Preferably, layer 27 extends from one of the walls 25, preferably from a lateral surface of one of walls 25, to the other wall 25 of the cell, preferably all the way to a lateral surface of the other wall 25. Layer 27 preferably extends in the row direction of the array, from wall 16. Layer 27 separates layer 26 from wells 12 and 24.

Layer 27 comprises two portions 27a and 27b. Portions preferably 27a and 27b each have a substantially constant thickness. Portion 27a corresponds, for example, to a high-voltage oxide, that is, an insulating layer configured to withstand a high voltage, for example greater than 10 V. Portion 27b corresponds to a tunnel oxide, that is, an insulating layer configured to be crossed by charges, according to the tunnel effect. Portion 27a has a greater thickness than portion 27b. Preferably, the thickness of portion 27a is at least one and a half times greater, preferably at least twice greater, than the thickness of portion 27b. For example, the thickness of portion 27a is greater than 10 nm, for example greater than or equal to 15 nm. For example, the thickness of portion 27b is greater than 5 nm, for example greater than or equal to 8 nm. For example, the thickness of portion 24b is substantially equal to 8 nm. For example, the thickness of portion 24a is substantially equal to 15 nm or to 22 nm.

Portion 27a extends over wells 12 and 22. Portion 27b extends over well 24. Preferably, portion 27a does not extend over well 24. Preferably, portion 27b does not extend over wells 12 and 22. The separation between portions 24a and 24b is preferably located on wall 16.

Preferably, layer 26 extends continuously opposite the entire upper surface of wells 12 and 14. Layer 26 extends, in the column direction, across the entire width of wells 22 and 24. Preferably, layer 26 extends from one of walls 25 to another wall 25 of the cell. Layer 26 preferably extends in the row direction of the array from well 22 to well 24.

Layer 29 preferably entirely covers layer 26. Preferably, layer 29 covers the upper surface of layer 26 and lateral surfaces of layer 26, for example the lateral surfaces of layer 26 in the column direction of the array. Preferably, layer 29 has a dimension, in the row direction of the array, substantially equal to the dimension of layer 26 in the row direction.

Layer 28 preferably entirely covers layer 29. Layer 28 is separated from layer 26 by layer 29. Preferably, layer 28 has a dimension, in the row direction, substantially equal to the dimension of layer 26 in the row direction.

Preferably, layer 28 is common to a plurality of cells in a same column, preferably to all the cells in a column. Thus, layer 28 preferably covers the layers 26 of a plurality of cells of a same column, and covers the walls 25 separating the cells.

The cell further comprises contact elements 30 and 32, for example conductive vias. Elements 30 and 32 are for example made of a metal. Element 30 is in contact with well 22 and element 32 is in contact with well 24. Elements 30 and 32 are not in contact with layers 26 and 28. Element 30 is preferably not in contact with well 12. Element 32 is preferably not in contact with well 14. Elements 30 and 32 are each coupled to a connection element forming a bit line.

Cell 10 is formed of two MOSFETs (Metal Oxide Semiconductor Field Effect Transistor). An N-channel transistor is formed of layer 18, well 12, and well 22, layers 26, 27, 28, and 29 forming the gate. The other P-channel transistor is formed of well 12, well 14, and well 24, layers 26, 27, 28, and 29 forming the gate.

Layer 18 is preferably common to all the memory cells of the type of cell 10 in a same array of cells.

Wall 16 is preferably common to all the cells in the column of the array. Wall 16 extends from one cell to a neighboring cell, crossing insulating walls 25.

The row of the cell array comprises, for example, neighboring cells symmetrical to one another along a plane of symmetry parallel to plane D-D and located, for example, on the left-hand side of view A. Wells 12 and 22 then extend to the left in view A so as to form shapes similar to those shown in FIG. 1. Similarly, well 24 and well 14 are, for example, common with a neighboring cell on the same row of the array located on the right-hand side of view A.

Preferably, the wells 22 of a same row of the array are coupled to one another via elements 30 and possibly other connection elements, not shown. Similarly, the wells 24 of a same row of the array are coupled together via elements 32 and possibly other connection elements, not shown.

Further, well 12 and well 14 are preferably common to all the cells in the column of the array. Wells 12 and 14 extend under walls 25. For example, wells 12 and 14 are each coupled by an end-of-line contact to a node of application of a voltage.

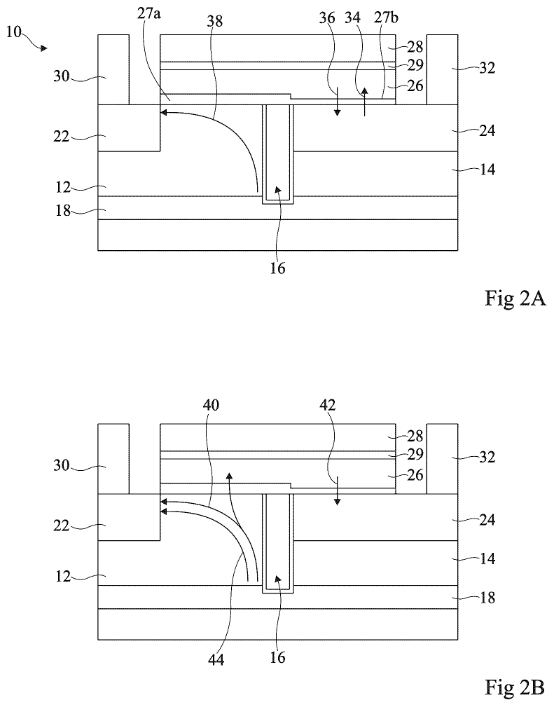

FIG. 2A and FIG. 2B show operating modes of the cell of FIG. 1.

FIG. 2A shows an operating mode of the cell of FIG. 1. More specifically, FIG. 2A shows an EEPROM-type operating mode. FIG. 2A comprises three arrows 34, 36, 38 respectively illustrating a cell write step, a cell erase step, and a cell readout step.

During the cell write step, the different portions of the cell are biased in such a way that electrons stored in well 24 are injected into layer 26 through portion 27b by tunnel effect. For example, cells 12, 22, 14, and 24 are set to a reference potential, for example, the ground. For example, layer 18 is set to a reference potential, for example the ground. For example, layer 28 is set to a positive potential, for example substantially equal to 14 V. Core 16a is, for example, set to a reference potential, for example the ground.

During the cell erase step, the different portions of the cell are biased in such a way that the electrons stored in layer 26, preferably all the electrons having been injected during the writing step, are injected into well 24 through portion 27b by tunnel effect.

The placing of well 24, that is, the fact for well 24 to extend all the way to wall 16, enables to use various potential values for the erase step.

Thus, according to a first example of an erase step, wells 12, 22, 14, and 24 are set to a reference potential, for example, the ground. For example, layer 18 is set to a reference potential, for example, the ground. For example, layer 28 is set to a negative potential, for example substantially equal to −14 V. Core 16a is, for example, set to a reference potential, for example the ground.

According to a second example of an erase step, wells 12, 22, 14 are set to a reference potential, for example the ground. For example, layer 18 is set to a reference potential, for example the ground. For example, layer 28 is set to a negative potential, for example substantially equal to −7 V. For example, well 24 is set to a positive potential, for example substantially equal to 7 V. Core 16a is for example set to a reference potential, for example the ground.

During the cell readout step, the different portions of the cell are biased so as to form a current between layer 18 and well 22. The value of the current determines the value of the data item stored in the cell. For example, cells 12, 14, and 24 are set to the same reference potential, for example the ground. Layer 18 is, for example, similarly set to the reference potential. Well 22 is set to a potential higher than the potential to which layer 18 is set. Well 22 is preferably set to a positive potential, for example a potential in the range from 0 V to 1 V, for example substantially equal to 0.7 V. Further, layer 28 is set to a potential lower than the potential to which well 22 is set, preferably to reference potential GND. Wall 16 is set to a potential higher than the potential to which well 22 is set. For example, wall 16 is set to a potential in the range from 1 V to 5 V.

FIG. 2B shows an operating mode of the cell of FIG. 1. More specifically, FIG. 2B shows an eSTM-type operating mode. FIG. 2B comprises three arrows 40, 42, 44 respectively illustrating a cell write step, a cell erase step, and a cell readout step.

The readout and erase steps, illustrated by arrows 42 and 44, are for example identical to the readout and erase steps of the operating mode described in relation with FIG. 2A.

During the cell write step, the different portions of the cell are biased in such a way that, during the write step, a current, represented by arrow 40, is formed between layer 18 and well 22, along wall 16 and layer 26. The potentials of well 22, of layers 28 and 18, and of wall 16 are such that a phenomenon of hot carrier injection occurs. Thus, carriers, here, electrons e-, thus enter layer 26 through layer 27 and remain trapped therein. For example, wells 12, 14, and 24 are respectively set to a reference potential, for example, the ground. For example, well 22 is set to a potential substantially equal to 4.5 V. For example, layer 18 is set to a reference potential, for example, the ground. For example, layer 28 is set to a potential substantially equal to 10 V.

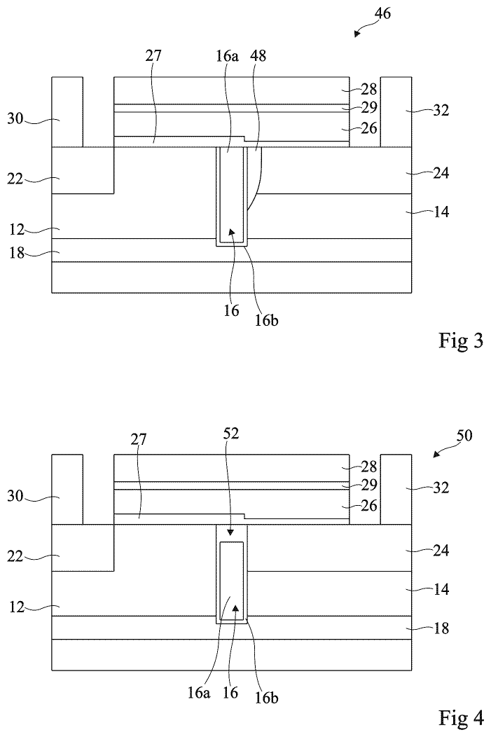

FIG. 3 shows another embodiment of a memory cell 46.

Memory cell 46 comprises the same elements as the cell 10 of FIG. 1. These elements will not be described again in detail.

Memory cell 46 differs from the memory cell 10 of FIG. 1 in that cell 46 comprises an insulating region 48. Region 48 is located between well 24 and the wall 16, more precisely between well 24 and cover 16b. Well 24 is thus separated, preferably entirely, from wall 16 by region 48. Region 48 preferably extends from the upper surface level of well 24 to a level located in well 14. Region 48 extends along the entire height of well 24. A portion of well 14 is for example separated from wall 16 by region 48. Preferably, region 48 does not extend along the entire height of well 14. Thus, a portion of the well 14 is not separated from wall 16 by region 48 and is preferably in contact with cover 16b.

Region 48 is preferably made of a material other than the material of cover 16b. Region 48 is for example made of silicon nitride.

Region 48 corresponds, for example, to a shallow trench isolation (STI) having been partially etched to form wall 16.

FIG. 4 shows another embodiment of a memory cell 50.

Memory cell 50 comprises the elements of the cell 10 of FIG. 1. These elements will not be described again in detail.

Memory cell 50 differs from memory cell 10 of FIG. 1 in that cell 50 comprises an insulating region 52. Region 52 is located between core 16a and layer 27. Core 16a is thus separated from layer 27 by region 52. The upper surface of core 16a is located, for example, at a level between the upper surface level of well 24 and the lower surface level of well 24. The upper surface of core 16a is separated by region 52 from the lower surface of layer 27, that is, separated from the upper surface of wells 12 and 24, by a distance shorter than 15 nm, for example shorter than 10 nm. A portion of well 24 is thus separated from well 12 by region 52. Region 52 is for example made of the material of cover 16b. Region 52 is, for example, a portion of cover 16b.

The features of FIGS. 3 and 4 may be combined so as to form a cell comprising the elements of the cell of FIG. 1, region 48, and region 52.

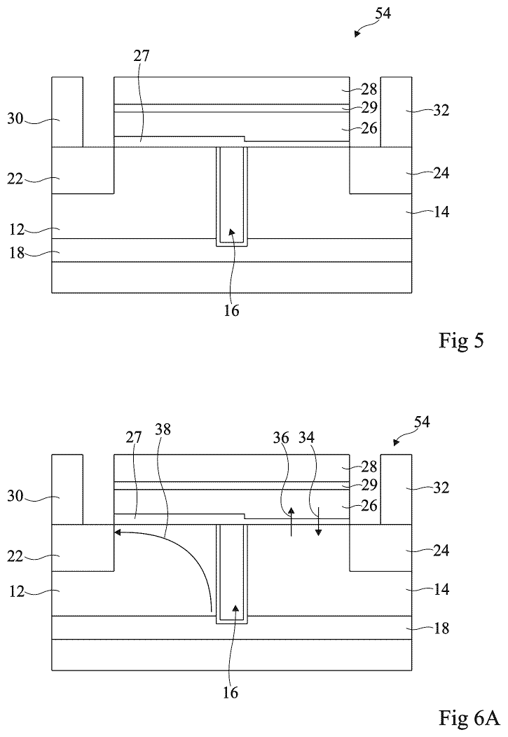

FIG. 5 shows another embodiment of a memory cell 54.

Memory cell 54 comprises the elements of the cell 10 of FIG. 1. These elements will not be described again in detail.

Cell 54 differs from cell 10 in that well 24 is separated from wall 16 by a portion of well 14. In other words, a portion of well 14 is located between well 24 and wall 16. Wall 16 and well 24 are thus not in contact with each other. Preferably, layer 26 is located opposite the portion of well 14 separating well 24 and wall 16. Preferably, layer 26 is not located opposite well 24.

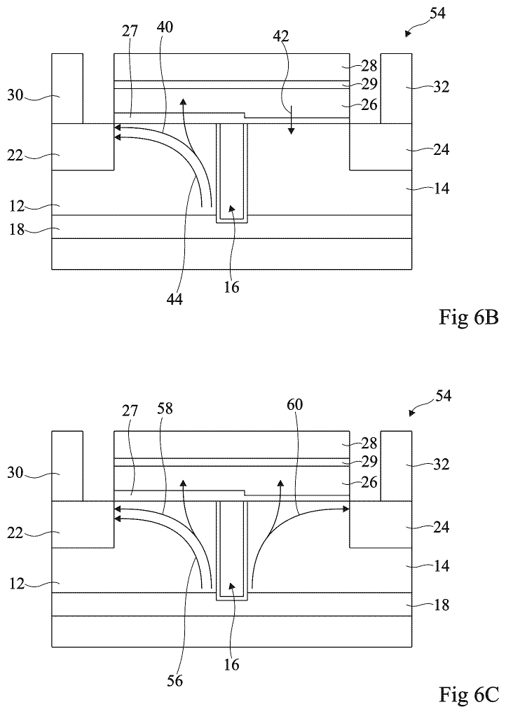

FIG. 6A, FIG. 6B, and FIG. 6C show operating modes of the cell of FIG. 5.

FIG. 6A shows an operating mode of the cell of FIG. 5. More specifically, FIG. 6A shows an EEPROM-type operating mode. FIG. 6A comprises three arrows 34, 36, 38 respectively illustrating a cell write step, a cell erase step, and a cell readout step.

The operating mode of cell 54 illustrated in FIG. 6A is identical to the operating mode of cell 10 illustrated in FIG. 2A. The operating mode differs only in that, in the absence of the portion of well 24 in contact with wall 16, the erase step cannot be performed with certain biasing values. Thus, in the operating mode of FIG. 6A, the erase step can be carried out as described in relation with FIG. 2A, wells 14 and 24 being biased to a reference potential, for example the ground, and layer 28 being biased to a negative potential, for example lower than-10 V, for example substantially equal to −14 V. It is however not possible to negatively bias well 14, except by inverting the conductivity types, that is, if 14 is of type N and well 24 is of type P.

FIG. 6B shows an operating mode of the cell of FIG. 5. More specifically, FIG. 6B shows an eSTM-type operating mode. FIG. 6B comprises three arrows 40, 42, 44 respectively illustrating a cell write step, a cell erase step, and a cell readout step.

The operating mode of cell 54 illustrated in FIG. 6A is identical to the operating mode of cell 10 illustrated in FIG. 2A.

FIG. 6C shows an operating mode of the cell of FIG. 5.

FIG. 6C comprises an arrow 58 illustrating the write and erase steps of a first variant of the operating mode of FIG. 6C.

During the write and erase steps of the first variant, the different portions of the cell are biased in such a way that a current, represented by arrow 58, is formed between layer 18 and well 22, along wall 16 and layer 26. The potentials of well 22, of layers 28 and 18, and of wall 16 are such that a phenomenon of hot carrier injection occurs. Thus, carriers, electrons e-during the write step and holes e+during the erase step, enter layer 26 through layer 27, and more precisely through portion 27a of layer 27. For example, wells 12, 14, 24 are respectively set to a reference potential, for example the ground. For example, well 22 is set to a positive potential, for example substantially equal to 4.5 V. For example, layer 18 is set to a reference potential, for example the ground. For example, layer 28 is set to a positive potential during the write step, for example substantially equal to 10 V, and to a negative potential during the erase step, for example substantially equal to −10 V.

FIG. 6C shows an arrow 60 illustrating the write and erase steps of a second variant of the operating mode of FIG. 6C.

The second variant differs from the first variant in that carriers, electrons e-during the write step and holes e+during the erase step, enter layer 26 through layer 27, and more precisely through portion 27b of layer 27 and not through portion 27a of layer 27. The potentials applied in the second variant are, for example, the same as the potentials applied in the first variant with the exception of the potential applied to well 22 and of the potential applied to well 24. In the second variant, the potential applied to well 22 is preferably a reference potential, for example the ground, and the potential applied to well 24 is a positive potential, for example substantially equal to 4.5 V. As a variant, the potentials applied in the second variant are different from the potentials applied in the first variant, the thickness difference of layer 27 affecting the cell coupling factors.

FIG. 6C shows an arrow 56 illustrating the step of reading from cell 54. The readout step is, for example, identical to the previously-described readout steps. The readout step is applicable to the two variants of the operating mode.

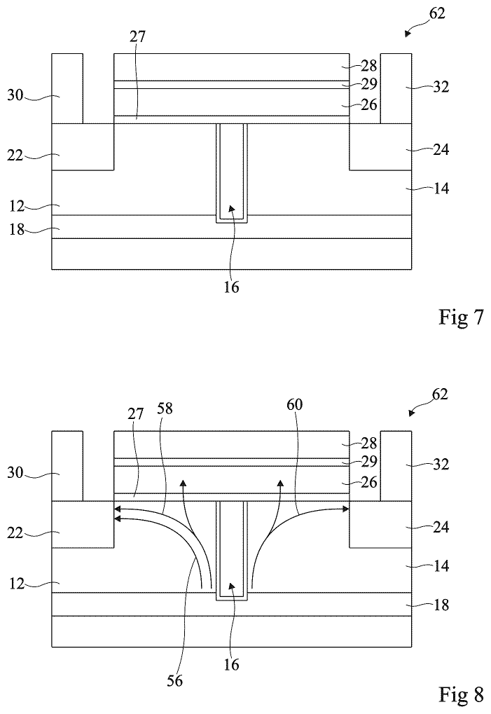

FIG. 7 shows another embodiment of a memory cell 62.

Memory cell 62 comprises the elements of the cell 54 of FIG. 5. These elements will not be described again in detail.

Cell 62 differs from cell 54 in that layer 27 does not comprise portions 27a and 27b. In other words, the portions of layer 27 covering wells 12 and 14 preferably have a constant thickness and having substantially the same thickness. The portions of layer 27 covering wells 12, 14, 22, 24 preferably have a constant thickness and having substantially the same thickness. Layer 27 preferably has a constant thickness.

FIG. 8 shows an operating mode of the cell of FIG. 7.

The operating mode of cell 62 is identical to the operating mode described in relation with FIG. 6C.

Thus, FIG. 6C comprises an arrow 58 illustrating the write and erase steps of a first variant of the operating mode of FIG. 8, identical to the first variant described in relation with FIG. 6C, and an arrow 60 illustrating the write and erase steps of a second variant of the operating mode of FIG. 8, identical to the second variant described in relation with FIG. 6C.

An advantage of the embodiments is that it is possible to use the same memory cells to implement different operating modes. Thus, the same cells can be used for eSTM-type memories and EEPROM-type memories.

Another advantage of the described embodiments is that they enable to have a cell-by-cell programming.

Various embodiments and variants have been described. Those skilled in the art will understand that certain features of these various embodiments and variants may be combined, and other variants will occur to those skilled in the art. In particular, the features of the embodiments of FIGS. 3 and 4 can be applied to the embodiments of FIGS. 5 and 7.

Finally, the practical implementation of the described embodiments and variants is within the abilities of those skilled in the art based on the functional indications given hereabove.

What is claimed is:

1. An electronic device comprising:
a memory cell, the memory cell comprising:
a first doped semiconductor well of a first conductivity type;
a second doped semiconductor well of the first conductivity type;
a first layer in contact with a lower surface of the first and second wells;
an insulated conductive wall separating the first and second wells;
a third semiconductor well located in the first well, the third well being doped with a second conductivity type opposite to the first conductivity type;
a fourth semiconductor well located in the second well, the fourth well being doped with the second conductivity type; and
a stack of layers extending over the first and second wells and the wall, the stack comprising a second insulating layer, a third layer forming a floating gate, a fourth insulating layer, and a fifth layer forming a control gate.

2. The device according to claim 1, wherein the fourth well separates the second well from the second layer.

3. The device according to claim 1, wherein the fourth well is separated from the wall by a portion of the second well.

4. The device according to claim 1, wherein the conductive insulating wall comprises a conductive core and an insulating cover.

5. The device according to claim 4, wherein a portion of the cover is covered by an insulating region made of a first material different from a second material of the cover, the region separating the fourth well from the wall, the second well being in contact with the wall.

6. The device according to claim 4, wherein the core extends from the lower surface of the second layer to a level in the first layer.

7. The device according to claim 4, wherein the core is separated from the second layer by a portion of the cover.

8. The device according to claim 1, wherein the second layer comprises a first portion having a first thickness and a second portion having a second thickness smaller than the first thickness, the first portion being located opposite the first well and the second portion being located opposite the second well.

9. The device according to claim 8, wherein the first thickness is at least one and a half times greater than the second thickness.

10. A method of using an electronic device comprising a memory cell comprising a first doped semiconductor well of a first conductivity type, a second doped semiconductor well of the first conductivity type, a first layer in contact with a lower surface of the first and second wells, an insulated conductive wall separating the first and second wells, a third semiconductor well located in the first well, the third well being doped with a second conductivity type opposite to the first conductivity type, a fourth semiconductor well located in the second well, the fourth well being doped with the second conductivity type, and a stack of layers extending over the first and second wells and the wall, the stack comprising a second insulating layer, a third layer forming a floating gate, a fourth insulating layer, and a fifth layer forming a control gate, the method comprising:
reading a first data item contained in the cell;
writing a second data item into the cell; and
erasing the cell.

11. The method according to claim 10, wherein the fourth well separates the second well from the second layer, and the method comprises:
during the writing or the erasing, biasing the cell such that charges are injected into the third layer from the fourth well through the second layer by tunnel effect.

12. The method according to claim 10, wherein the fourth well is separated from the wall by a portion of the second well, and the method comprises:
during the writing or the erasing, biasing the cell such that charges are injected into the third layer from the second well through the second layer by tunnel effect.

13. The method according to claim 10, wherein the conductive insulating wall comprises a conductive core and an insulating cover.

14. The method according to claim 13, wherein a portion of the cover is covered by an insulating region made of a first material different from a second material of the cover, the region separating the fourth well from the wall, the second well being in contact with the wall.

15. The method according to claim 13, wherein the core extends from the lower surface of the second layer to a level in the first layer.

16. The method according to claim 13, wherein the core is separated from the second layer by a portion of the cover.

17. The method according to claim 10, wherein the second layer comprises a first portion having a first thickness and a second portion having a second thickness, smaller than the first thickness, the first portion being located opposite the first well and the second portion being located opposite the second well.

18. The method according to claim 17, wherein the first thickness is at least one and a half times greater than the second thickness.

19. The method according to claim 10, comprising:
during the reading, biasing the cell to form a current between the first layer and the third well.

20. The method according to claim 10, comprising:
during the writing or the erasing, biasing the cell such that a current is formed between the first layer and the third well, charges being injected into the third layer by injection of hot carriers through the second layer.
